(19) United States
(12) Patent Application Publication
(10) Pub. No.: US 2008/0005896 A1
(43) Pub. Date: Jan. 10, 2008

(54) Method for fabricating multi-layered flexible printed circuit board without via holes

(75) Inventors: Syh-Tau Yeh, Hsien (TW); Yao-Ming Chen, Chong-Li City (TW)

Correspondence Address: BIRCH STEWART KOLASCH & BIRCH, PO BOX 747, FALLS CHURCH, VA, 22040-0747, US

(73) Assignee: TEAMCHEM COMPANY

(21) Appl. No.: 11/480,499

(22) Filed: Jul. 5, 2006

(51) Int. Cl. H05K 3/00

(52) U.S. Cl. 29/829; 29/831

(57) ABSTRACT

A method for fabricating a multi-layered flexible printed circuit board without via holes is disclosed herein, which includes the steps of: providing a flexible printed circuit board formed with a circuit thereon in advance; and fan-folding or rolling the flexible printed circuit board to build up a plurality of layers in order to obtain the multi-layered flexible printed circuit board without via holes; thereby being capable of solving the problems resulting from the via holes formed on a conventional flexible printed circuit board.

### BACKGROUND OF THE INVENTION

1. Field of the Invention

The present invention relates to a method for fabricating a multi-layered printed circuit board, and in particular to a method for fabricating a multi-layered flexible printed circuit board without via holes.

2. The Prior Arts

Conventional multi-layered flexible printed circuit boards, whether fabricated with Pre-preg hot press lamination or with Build-up Process, utilize via holes to interconnect conductive traces on adjacent layers in order to enable three dimensional arrangement of circuits and substantially reduce the space occupied by the printed circuit boards. However, the conventional methods of fabricating the multi-layered flexible printed circuit boards not only are complicated in fabricating processes, but also cause problems in fabricating. For example, in hot press lamination, the dimension of the flexible printed circuit board can not be easily controlled precisely due to its expansion/contraction. As a result, misalignment occurs when aligning the conductive traces on different layers of the flexible printed circuit board therebetween. Furthermore, to utilize the substrate surface more efficiently, there is a trend to have smaller and smaller via holes, which increases the difficulty in plating the via holes substantially. Additionally, with the increase of trace density within unit area of the substrate, the difficulty of the fabricating process drastically increases as well.

In addition, there exist many problems in utilizing the multi-layered printed circuit boards with via holes. For example, the shape and size of such substrates are fixed and cannot be adjusted to fit to an inner space of electronic products, which hinders the efficient utilization of the space inside the electronic products. To overcome this problem, U.S. Pat. No. 6,005,766 disclosed a multi-layered printed circuit board and a method of fabricating the same, in which a multi-layered board meeting the required electronic product in thickness is fabricated first, and then, is cut off in the redundant area of the substrate to obtain a shape fitting with that of the electronic product. Though this fabricating method solves part of the aforementioned problems, it is too complicated and expensive.

Moreover, in the application of high frequency electronic products, via holes of conventional printed circuit boards are one of the major factors causing the signal loss of electronic products. When the frequency is higher than 1 GHz, the signal loss becomes very obvious. The higher the frequency is, the more obvious the signal loss becomes. This phenomenon is known as via resonance. To solve this problem, a method was disclosed in U.S. Pat. No. 7,013,452, in which two compensating circuits having the same circuit length are added in a circuit layout design. Though this method solves part of the problems, it complicates the circuit design substantially. Another method was disclosed in U.S. Pat. No. 6,593,535 to solve the problem of via resonance, in which a multi-layered wedge-shaped conductive material is inserted into a non-plated via hole to interconnect the traces on different layers. Still another method was disclosed in U.S. Pat. No. 6,661,316, in which appropriate inductance and capacitance are added to a circuit according to actual operational frequency to adjust the frequency response. Though these aforementioned methods solve part of the aforementioned problems, in mass production, they are confronted with problems of high manufacturing cost and complicated fabricating process, thereby resulting in difficulty in their actual applications.

### SUMMARY OF THE INVENTION

A primary objective of the present invention is to provide a method for fabricating a multi-layered flexible printed circuit board without via holes, which can solve the aforementioned problems resulting from the via holes formed on the conventional multi-layered printed circuit board.

To achieve the aforementioned objective, a method for fabricating a multi-layered flexible printed circuit board without via holes in accordance with the present invention comprises the steps of: providing a flexible printed circuit board formed with a circuit thereon in advance, the circuit being formed on a single side of the flexible printed circuit board; and fan-folding or rolling the flexible printed circuit board to build up a plurality of layers, wherein the circuit is electrically connected with pads, the pads located on an outer surface of the flexible printed circuit board after folded or rolled, for connection with an external component.

In accordance with the present invention, a multi-layered flexible printed circuit board without via holes can be obtained. Accordingly, the problems resulting from via holes formed on the conventional multi-layered flexible printed circuit board can be solved.

Compared with the conventional multi-layered flexible printed circuit board, the method of the present invention needs only a single-sided flexible printed circuit board to fabricate a multi-layered flexible printed circuit board. The multi-layered structure can substantially reduce the space occupied by the circuit board inside electronic products.

The present invention will be apparent to those skilled in the art by reading the following detailed description of preferred embodiments thereof with reference to the attached drawings.

### BRIEF DESCRIPTION OF THE DRAWINGS

FIG. 1 is a perspective schematic view of a flexible printed circuit board in accordance with the present invention.

FIG. 2 is a perspective schematic view showing a method of folding the flexible printed circuit board of FIG. 1.

FIG. 3 is a perspective schematic view of a fan-folded-type multi-layered flexible printed circuit board in accordance with an embodiment of the present invention.

FIG. 4 is a perspective schematic view showing another method of folding the flexible printed circuit board of FIG. 1.

FIG. 5 is a perspective schematic view of a rolled-type multi-layered flexible printed circuit board in accordance with another embodiment of the present invention.

### DETAILED DESCRIPTION OF THE PREFERRED EMBODIMENT

In a method for fabricating a multi-layered printed circuit board without via holes in accordance with the present invention, a flexible printed circuit board is fan-folded repeatedly to build up a plurality of layers in order to accommodate a large amount of conductive traces within a small space inside an electronic product.

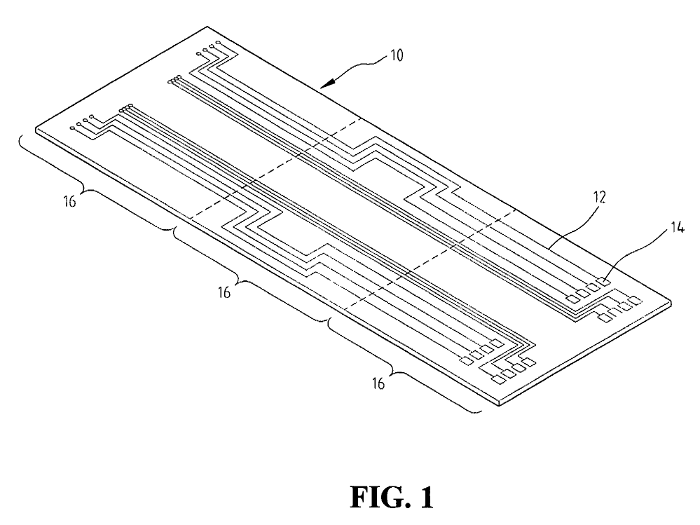

Please to refer to FIGS. 1-3, which show a method for fabricating a multi-layered printed circuit board in accordance with an embodiment of the present invention. Also referring to FIG. 1, first, a flexible printed circuit board 10 with a required circuit 12 formed on a single side of the board in advance is provided. The wiring of the circuit 12 may be obtained using prior techniques. The circuit 12 is formed on each area 16 of the flexible printed circuit board 10. After the flexible printed circuit board 10 is folded, each area 16 is configured to be one layer of the multi-layered flexible printed circuit board 10. In addition, each conductive trace of the circuit 12 is electrically connected to a pad 14, and the pad 14 is located on an outer surface of the flexible printed circuit board 10 after it is folded, for connection with an external component.

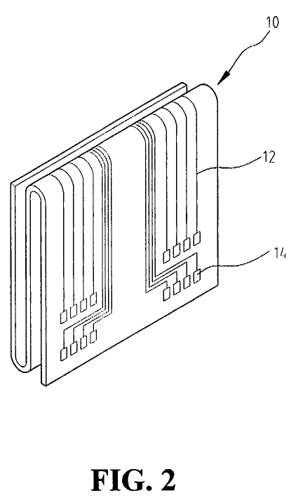

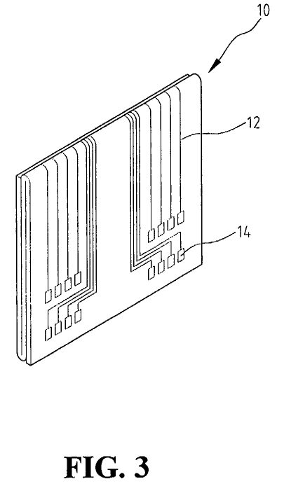

Before the flexible printed circuit board 10 is folded, the circuit 12 has to be protected and insulated with coverlay or solder mask with the pad 14 left bare. Then the flexible printed circuit board 10 is fan-folded repeatedly (see FIG. 2) to build up a plurality of layers like a sandwich structure (see FIG. 3).

The aforementioned built multiple layers of the printed circuit board 10 may be fixed by any conventional methods, such as stapling, riveting, adhesion, binding, or other conventional lamination techniques.

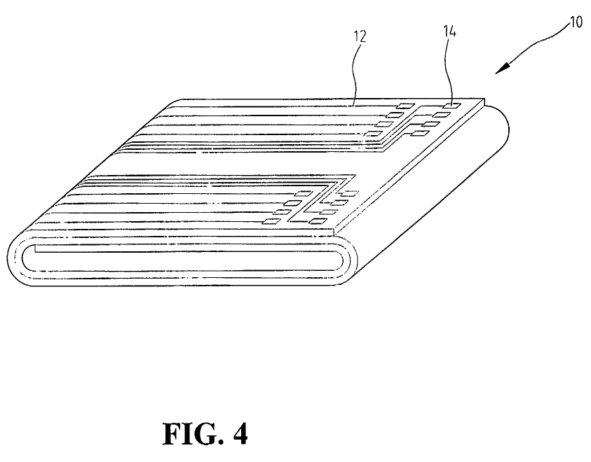

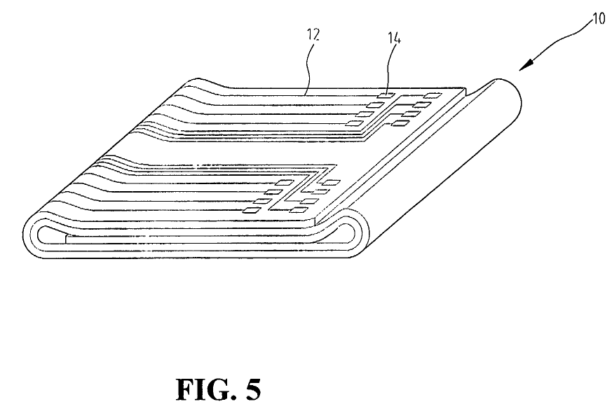

With reference to FIG. 4, which is a second embodiment of the method in accordance with the present invention, the flexible printed circuit board 10 is rolled up to build up a plurality of layers like an egg roll structure (see FIG. 4), and then is pressed for fixation (see FIG. 5).

A substrate applicable to the present invention is a single-sided thin-film flexible printed circuit board. There is no limitation to the type of the flexible printed circuit board. It may be a two-layer flexible copper clad laminate (FCCL) formed with polyimide film and copper foil, a three-layer FCCL formed with polyimide film, adhesive, and copper foil, or other flexible printed circuit board.

The electrically conductive layer for the circuit on the printed circuit board applicable to the present invention may be fabricated with but not limited to copper foil, electric deposited copper foil, roll annealed copper foil, heat-treated electrolytic copper foil, or electrically conductive aluminum foil. Roll annealed copper foil or aluminum foil are preferred if the flexibility of the printed circuit board is of concern. The thickness of the aforementioned electrically conductive layer may be fabricated according to the requirements, and is not specifically limited in the present invention.

Although the present invention has been described with reference to the preferred embodiment thereof, it is apparent to those skilled in the art that a variety of modifications and changes may be made without departing from the scope of the present invention which is intended to be defined by the appended claims.

What is claimed is:

1. A method for fabricating a multi-layered flexible printed circuit board without via holes, comprising the steps of:
(1) providing a flexible printed circuit board formed with a circuit thereon in advance, said circuit being formed on a single side of said flexible printed circuit board; and
(2) fan-folding or rolling said flexible printed circuit board to build up a plurality of layers, wherein said circuit is electrically connected with pads, said pads located on an outer surface of said flexible printed circuit board after folded or rolled, for connection with an external component.

2. The method as claimed in claim 1, wherein a surface of said flexible printed circuit board where said circuit is formed, is covered with an insulating layer, with said pads left bare.

3. The method as claimed in claim 2, wherein said insulating layer is one of coverlay and solder mask.

4. The method as claimed in claim 1, further the step of fixing said fan-folded or rolled flexible printed circuit board after said step (2).

5. The method as claimed in claim 1, wherein said flexible printed circuit board is a single-sided thin-film flexible printed circuit board.

6. The method as claimed in claim 1, wherein an electrically conductive layer served as said circuit on said printed circuit board is made of the material selected from the group consisting of electric deposited copper foil, roll annealed copper foil, heat-treated electrolytic copper foil, and electrically conductive aluminum foil.
